(19) United States
(12) Patent Application Publication
(10) Pub. No.: US 2026/0186417 A1
(43) Pub. Date: Jul. 2, 2026

(54) SUBSTRATE TREATMENT APPARATUS AND SUBSTRATE TREATMENT METHOD

(71) Applicant: SEMES CO., LTD., Cheonan-si (KR)

(72) Inventors: Beom Jin SHIN, Seoul (KR); Sung Yong LEE, Yongin-si (KR); Sang Bok HAN, Asan-si (KR)

(21) Appl. No.: 19/339,628

(22) Filed: Sep. 25, 2025

(30) Foreign Application Priority Data
Dec. 30, 2024 (KR) 10-2024-0200585

(51) Int. Cl. G03F 7/16; G03F 7/00

(52) U.S. Cl. CPC G03F 7/16; G03F 7/70866

(57) ABSTRACT

A substrate treatment apparatus includes a nozzle portion applying a treatment liquid to a substrate, and a liquid supply unit supplying the treatment liquid to the nozzle portion. The liquid supply unit includes a storage container storing the treatment liquid, a pump unit including a first pump portion filled with the treatment liquid before being supplied to the nozzle portion, and a second pump portion supplying the treatment liquid to the nozzle portion, the first pump portion being connected to the second pump portion via a supply line and controlling supply pressure of the treatment liquid supplied to the second pump portion, a valve opening and closing the pump unit and the supply line, and a control unit maintaining the supply pressure at atmospheric pressure when the valve is closed and controlling the supply pressure to vary to a target pressure when the valve is opened.

### CROSS-REFERENCE TO RELATED APPLICATION(S)

This application claims benefit of priority to Korean Patent Application No. 10-2024-0200585 filed on Dec. 30, 2024 in the Korean Intellectual Property Office, the disclosure of which is incorporated herein by reference in its entirety.

### BACKGROUND

### 1. Field

The present disclosure relates to a substrate treatment apparatus and a substrate treatment method.

### 2. Description of Related Art

In semiconductor manufacturing, photolithography is the process of forming a required pattern on a wafer. The photolithography process is typically performed in a spinner system, which is connected to an exposure system and sequentially processes the coating, exposure, and development processes. These spinner systems sequentially or selectively perform the Hexamethyl disilazane (HMDS) process, coating, baking, and development processes.

The coating process involves applying a treatment liquid supplied via a liquid supply unit to the substrate. When the treatment liquid is transported by the liquid supply unit, pressure hunting occurs within the supply pipe through which the treatment liquid passes, by the pump unit. This not only reduces the pump unit's control efficiency, but may also lead to various problems, such as water hammer, which may damage the supply pipe.

### SUMMARY

An aspect of the present disclosure is to provide a substrate treatment apparatus and a substrate treatment method, which may prevent negative pressure from being generated in a treatment liquid supply pipe during the process of supplying a treatment liquid to a nozzle portion, and which may reduce occurrence of a water hammer phenomenon and pressure hunting that may occur in a pump unit during the process of supplying a treatment liquid.

According to an aspect of the present disclosure, a substrate treatment apparatus includes a nozzle portion configured to apply a treatment liquid to a substrate, and a liquid supply unit configured to supply the treatment liquid to the nozzle portion. The liquid supply unit includes a storage container configured to store the treatment liquid, a pump unit including a first pump portion filled with the treatment liquid before being supplied to the nozzle portion, and a second pump portion supplying the treatment liquid to the nozzle portion, the first pump portion being connected to the second pump portion via a supply line and controlling supply pressure of the treatment liquid supplied to the second pump portion, a valve configured to open and close the supply line, and a control unit configured to maintain the supply pressure at atmospheric pressure when the valve is closed and to control the supply pressure to vary to a target pressure when the valve is opened.

According to an aspect of the present disclosure, a substrate treatment method includes supplying a treatment liquid to a first pump portion, maintaining supply pressure of the treatment liquid at atmospheric pressure by the first pump portion, opening a supply line connecting the first pump portion and a second pump portion, and supplying the treatment liquid to the second pump portion, increasing the supply pressure of the treatment liquid to the second pump portion to a target pressure by the first pump portion, and supplying the treatment liquid to a nozzle portion by the second pump portion.

According to an aspect of the present disclosure, a substrate treatment apparatus includes a processing chamber having a processing space provided therein, a nozzle portion disposed in the processing space and applying a treatment liquid to a substrate, and a liquid supply unit supplying the treatment liquid to the nozzle portion. The liquid supply unit includes a storage container storing the treatment liquid, a trap tank connected to the storage container via a first supply line and temporarily storing the treatment liquid, a pump unit including a first pump portion connected to the trap tank via a second supply line, receiving the treatment liquid temporarily stored in the trap tank, and filled with the treatment liquid, and a second pump portion connected to the first pump portion via a third supply line and supplying the treatment liquid to the nozzle portion via a fourth supply line, the first pump portion regulating supply pressure of the treatment liquid supplied to the second pump portion via the third supply line, a valve opening and closing the third supply line, and a control unit configured to variably control the supply pressure of the treatment liquid. The control unit is configured to control the supply pressure to be maintained at atmospheric pressure when the valve is closed, and to control the supply pressure to increase to a target pressure when the valve is opened. The control unit is configured to control the supply pressure to increase to an initial pressure higher than the atmospheric pressure when the valve is opened, and then to gradually increase to the target pressure over time, and to control the treatment liquid to begin to be filled into the second pump portion after the supply pressure reaches the target pressure. The control unit is configured to control the valve to be closed again and to fill a new treatment liquid in the first pump portion, when the supply pressure reaches the target pressure and then the treatment liquid previously filled in the first pump portion is completely supplied to the second pump portion, and to control the supply pressure of the treatment liquid in the third supply line to become the atmospheric pressure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate treatment apparatus according to an embodiment;

FIG. 2 is a top view of the substrate treatment apparatus of FIG. 1, taken from the A-A direction;

FIG. 3 is a top view of the substrate treatment apparatus of FIG. 1, taken from the B-B direction;

FIG. 4 schematically illustrates a substrate treatment apparatus including a liquid supply unit according to an embodiment;

FIG. 5 is a graph schematically illustrating changes in supply pressure of a treatment liquid during movement of the treatment liquid in a substrate treatment apparatus including a liquid supply unit according to an embodiment;

FIG. 6 is a graph illustrating changes in supply pressure of a treatment liquid for each movement section of the treatment liquid in a substrate treatment apparatus including a liquid supply unit of the related art;

FIG. 7 is a graph illustrating changes in supply pressure of a treatment liquid according to each movement section of the treatment liquid in a substrate treatment apparatus including a liquid supply unit according to an embodiment of the present disclosure;

FIG. 8 illustrates a portion of the liquid supply unit of FIG. 4;

FIG. 9 illustrates a portion of a liquid supply unit according to another embodiment; and

FIG. 10 is a flowchart illustrating a substrate treatment method according to an embodiment.

### DETAILED DESCRIPTION

Hereinafter, with reference to the attached drawings, example embodiments will be described in detail so that those skilled in the art may easily practice the present disclosure. However, in describing example embodiments in detail, if a detailed description of related known functions or configurations is determined to unnecessarily obscure the gist of the present disclosure, such detailed descriptions will be omitted. Furthermore, the same reference numerals are used throughout the drawings for parts with similar functions and actions. Furthermore, in this specification, terms such as “on,” “upper,” “upper end,” “below,” “lower,” “lower end” and the like refer to the drawings, and terms such as “inner,” “outer,” and the like refer to the outer perimeter of the corresponding component. In practice, these terms may vary depending on the orientation of the elements or components.

In addition, throughout the specification, the term “including” a component does not exclude other components, unless otherwise specified, but rather implies the inclusion of other components.

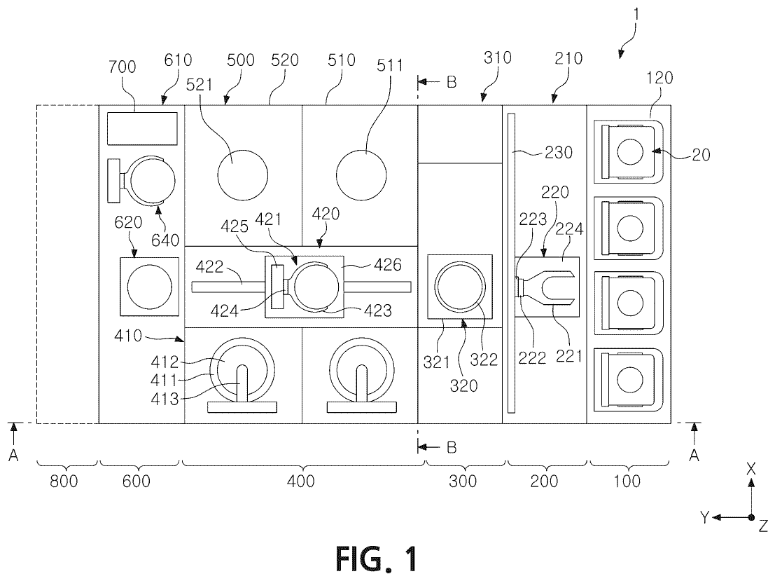

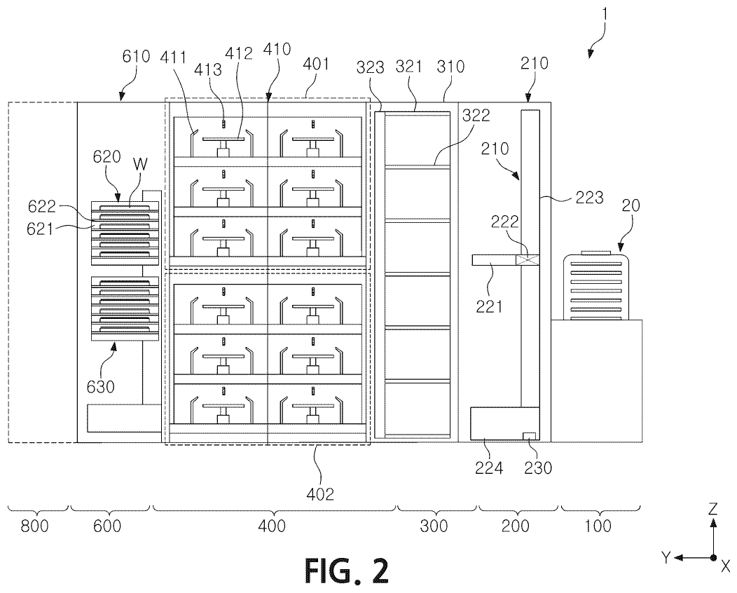

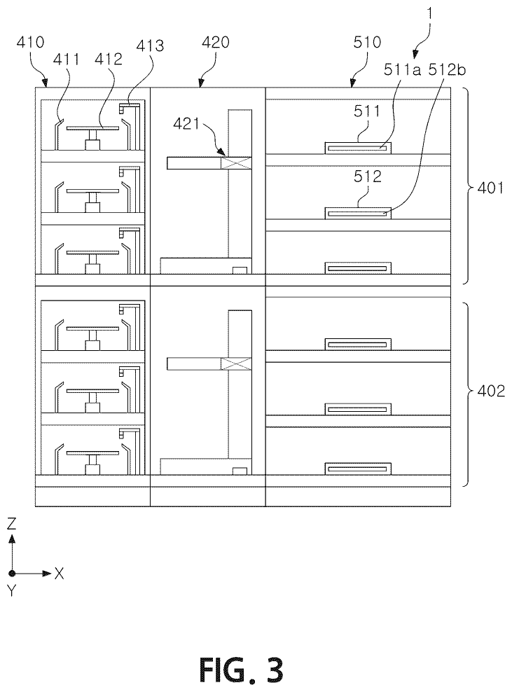

FIG. 1 is a top view of a substrate treatment apparatus, FIG. 2 is a view of the substrate treatment apparatus of FIG. 1 viewed from direction A-A, and FIG. 3 is a view of the substrate treatment apparatus of FIG. 1 viewed from direction B-B.

Referring to FIGS. 1 to 3, a substrate treatment apparatus 1 may include a load port 100, an index module 200, a buffer module 300, a coating and developing module 400, and a purge module 700. The load port 100, the index module 200, the buffer module 300, the coating and developing module 400, and the interface module 600 may be sequentially disposed in a row in one direction. The purge module 700 may be provided within the interface module 600. Alternatively, the purge module 700 may be provided at various locations, such as the location where the exposure device 800 is connected at the rear of the interface module 600 or on the side of the interface module 600. Hereinafter, the direction in which the load port 100, index module 200, buffer module 300, coating and developing module 400, and interface module 600 are disposed is referred to as the first direction (Y). The direction perpendicular to the first direction (Y) when viewed from above is referred to as the second direction (X), and the direction respectively perpendicular to both the first direction (Y) and the second direction (X) is referred to as the third direction (Z).

The substrate (W) may be transported while stored within a cassette 20. The cassette 20 may have a structure that may be sealed from the outside. For example, a Front Open Unified Pod (FOUP) with a door at the front may be used as the cassette 20.

Below, the load port 100, index module 200, buffer module 300, coating and developing module 400, interface module 600, and purge module 700 are described in detail.

The load port 100 may have a mounting plate 120 on which a cassette 20 containing a substrate (W) is placed. Multiple mounting plates 120 may be provided, and the mounting plates 120 may be disposed in a row along the second direction (X). While FIG. 1 illustrates an example in which four mounting plates 120 are provided, the number may vary.

The index module 200 may transfer the substrate (W) between the cassette 20 placed on the mounting plate 120 of the load port 100 and the buffer module 300. The index module 200 may include a frame 210, an index robot 220, and a guide rail 230.

The frame 210 is provided in the shape of a substantially rectangular parallelepiped with an interior that is hollow, and may be placed between the load port 100 and the buffer module 300. The frame 210 of the index module 200 may be provided at a lower height than a frame 310 of the buffer module 300.

The index robot 220 and the guide rail 230 may be disposed within the frame 210. The index robot 220 may be provided such that a hand 221 for directly handling a substrate (W) may move and rotate in a first direction (Y), a second direction (X), and a third direction (Z). The index robot 220 may include a hand 221, an arm 222, a support 223, and a pedestal 224. The hand 221 may be fixedly installed on the arm 222. The arm 222 may be provided with a flexible structure and a rotatable structure. The support 223 may be disposed such that the longitudinal direction thereof is in the third direction (Z). The arm 222 may be coupled to the support 223 to be movable along the support 223. The support 223 may be fixedly coupled to the pedestal 224. The guide rail 230 may be provided such that the longitudinal direction thereof is disposed in the second direction (X). The pedestal 224 may be coupled to the guide rail 230 to be linearly movable along the guide rail 230. In addition, although not illustrated, the frame 210 may further include a door opener for opening and closing the door of the cassette 20.

The buffer module 300 may include a frame 310, a first buffer 320, a second buffer 330, and a cooling chamber 340. The frame 310 is provided in the shape of a rectangular parallelepiped with an interior that is hollow, and may be disposed between the index module 200 and the coating and developing module 400. The first buffer 320, the second buffer 330, and the cooling chamber 340 may be positioned within the frame 310. The cooling chamber 340, the second buffer 330, and the first buffer 320 may be sequentially disposed from below along the third direction (Z). The first buffer 320 may be positioned at a height corresponding to a coating module 401 of the coating and developing module 400, and the second buffer 330 and the cooling chamber 340 may be provided at a height corresponding to a development module 402 of the coating and developing module 400.

The first buffer 320 and the second buffer 330 may each temporarily store a plurality of substrates (W). The first buffer 320 may have a housing 321 and a plurality of supports 322. In the first buffer 320, the supports 322 are disposed within the housing 321 and may be provided to be spaced apart from each other along a third direction (Z). The second buffer 330 may have a housing 331 and a plurality of supports 332. In the second buffer 330, the supports 332 are disposed within the housing 331 and may be provided to be spaced apart from each other along a third direction (Z). One substrate (W) may be disposed on each support 322 of the first buffer 320 and each support 332 of the second buffer 330. The housing 331 may have an opening in the direction in which the index robot 220 is provided, allowing the index robot 220 to load or unload a substrate (W) onto the support 332 within the housing 331.

The first buffer 320 has a structure generally similar to that of the second buffer 330. However, the housing 321 of the first buffer 320 may have an opening in the direction in which the first buffer robot 360 is provided and in the direction in which an application robot 421 located in the coating module 401 is provided. The number of supports 322 provided in the first buffer 320 and the number of supports 332 provided in the second buffer 330 may be the same or different. In one example, the number of supports 332 provided in the second buffer 330 may be greater than the number of supports 322 provided in the first buffer 320.

The cooling chamber 340 may cool each substrate (W). The cooling chamber 340 may include a housing 341 and a cooling plate 342. The cooling plate 342 may have an upper surface on which the substrate (W) is placed, and a cooling unit 343 for cooling the substrate (W). Various methods, such as cooling using cooling water or cooling using a thermoelectric element, may be used as the cooling unit 343. In addition, the cooling chamber 340 may be provided with a lift pin assembly for positioning the substrate (W) on the cooling plate 342. The housing 341 may have openings in the direction in which the index robot 220 is provided and in the direction in which the developing robot is provided so that the index robot 220 and the developing robot provided in the development module 402 may load or unload the substrate (W) onto or from the cooling plate 342. In addition, the cooling chamber 340 may be provided with doors for opening and closing the above-described openings.

Although the buffer module 300 has been described above as an embodiment including the configurations of the cooling chamber 340, the present disclosure is not limited thereto, and the cooling chamber 340 may be omitted as needed.

The coating module 401 may include a process for applying a photosensitive solution, such as photoresist, to a substrate (W), and a heat treatment process, such as heating and cooling, for the substrate (W) before and after the resist application process. The coating module 401 may include a coating chamber 410, a heat treatment chamber section 500, and a return chamber 420. The coating chamber 410, the return chamber 420, and the heat treatment chamber section 500 may be sequentially disposed along the second direction (X). For example, with respect to the return chamber 420, a coating chamber 410 may be provided on one side of the return chamber 420, and a heat treatment chamber section 500 may be provided on the other side of the return chamber 420.

The coating chamber 410 may be provided as a plurality of coating chambers, and respectively provided in plural in the third direction (Z). Furthermore, as illustrated in FIG. 1, a plurality of coating chambers 410 may be provided in the first direction (Y), or a single coating chamber 410 may be provided in the first direction (Y).

The heat treatment chamber section 500 includes a baking chamber 510 and a cooling chamber 520, and the baking chamber 510 and the cooling chamber 520 may be each provided in plural in the third direction (Z). The return chamber 420 may be positioned parallel to the first buffer 320 of the first buffer module 300 in the first direction (Y). The application robot 421 and a guide rail 422 may be positioned within the return chamber 420. The return chamber 420 may have a generally rectangular shape. The application robot 421 may transfer a substrate (W) between the baking chamber 510, the cooling chamber 520, the coating chamber 410, and the first buffer 320 of the first buffer module 300.

The guide rail 422 may be disposed so that the longitudinal direction thereof is parallel to the first direction (Y). The guide rail 422 may guide the application robot 421 to move linearly in the first direction (Y). The application robot 421 may have a hand 423, an arm 424, a support 425, and a pedestal 426. The hand 423 may be fixedly installed to the arm 424. The arm 424 may be provided with an elastic structure so that the hand 423 may move horizontally. The support 425 may be provided so that the longitudinal direction thereof is disposed in the third direction (Z). The arm 424 may be coupled to the support 425 to be linearly moved in the third direction (Z) along the support 425. The support 425 is fixedly connected to the pedestal 426, and the pedestal 426 may be connected to the guide rail 422 to be movable along the guide rail 422.

The coating chambers 410 may all have the same structure, but the types of treatment liquid used in respective coating chambers 410 may differ from each other. The treatment liquid may be a treatment liquid for forming a photoresist film or an anti-reflection film.

The coating chamber 410 may apply the treatment liquid onto a substrate (W). In the coating chamber 410, a treatment unit including a treatment container 411, a support portion 412, and a nozzle portion 413 may be provided.

For example, the coating chamber 410 has one treatment unit disposed along the first direction (Y). However, this arrangement is not limited thereto, and two or more treatment units may be disposed in a single coating chamber 410. Respective treatment units may have the same structure. However, the types of treatment liquid used in respective treatment units may differ from each other. The treatment container 411 of the coating chamber 410 may have an open top. The support portion 412 is positioned within the treatment container 411 and may support the substrate (W). The support portion 412 may be provided to be rotatable. The nozzle portion 413 may supply the treatment liquid onto the substrate (W) disposed on the support portion 412. The treatment liquid may be applied to the substrate (W) using a spin coat method. In addition, the coating chamber 410 may optionally further include a nozzle (not illustrated) for supplying a cleaning solution, such as deionized water (DIW), to clean the surface of the substrate (W) to which the treatment liquid has been applied, and a back rinse nozzle (not illustrated) for cleaning the lower surface of the substrate (W).

In the baking chamber 510, the substrate (W) may be heat-treated when the wafer (W) is mounted thereon by the application robot 421. In the baking chamber 510, a prebake process may be performed to remove organic substances or moisture from the surface of the substrate (W) by heating the substrate (W) to a predetermined temperature before applying the treatment liquid, or a soft bake process may be performed after applying the treatment liquid onto the wafer (W). After each heating process, a cooling process and the like may be performed to cool the substrate (W).

The baking chamber 510 may include a hot plate 511 and a heating unit 511a.

The heating unit 511a may heat the substrate (W) disposed inside the baking chamber 510. At this time, the substrate (W) is heated while the baking chamber 510 is sealed, and the heating unit 511a may heat the entire area of the substrate (W) to a uniform temperature. For example, the heating unit 511a may utilize a heating method utilizing heating wires installed on the interior of or the exterior surface of the hot plate 511. Furthermore, a heating method using a device such as a heater disposed within or outside the baking chamber 510 may be utilized. The heat treatment process described above may stabilize the liquid film formed by blowing organic substances onto the liquid film formed by applying the treatment liquid to the substrate (W).

Furthermore, the baking chamber 510 may further be equipped with a chill plate (not illustrated). The chill plate may receive cooling water from the cooling unit 910, described below, to cool the substrate (W). This prevents the substrate (W) from being heated to excessively high temperatures during the heat treatment process. The substrate (W) that has undergone the heat treatment process may be transported to a cooling chamber 520.

In the cooling chamber 520, a cooling process is performed to cool the substrate (W) before applying the treatment liquid. The cooling chamber 520 may be equipped with a cooling plate. The cooling plate may include a cooling unit that may utilize various methods, such as cooling with coolant or cooling using a thermoelectric element, to cool the substrate (W).

The interface module 600 may connect the coating and developing module 400 to an external exposure device 800. The interface module 600 includes an interface frame 610, a first interface buffer 620, a second interface buffer 630, and a transfer robot 640. The transfer robot 640 may transfer substrates returned to the first and second interface buffers 620 and 630 after the coating and developing module 400 has completed processing, to the exposure device 800. The first and second interface buffers 620 include a housing 621 and a support 622, and the transfer robot 640 and the application robot 421 may load and unload substrates (W) onto and from the support 622.

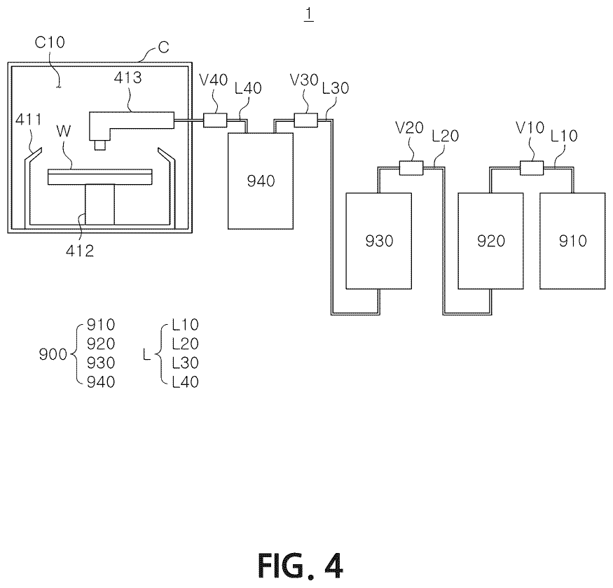

FIG. 4 schematically illustrates a substrate treatment apparatus including a liquid supply unit according to an embodiment.

Referring to FIG. 4, a substrate treatment apparatus 1 may include a liquid supply unit 900. The liquid supply unit 900 may include a storage container 910, a trap tank 920, a pump unit, and a control unit (not illustrated).

The liquid supply unit 900 may be connected to equipment that requires application of a treatment liquid onto a substrate (W) during substrate treatment processes. The substrate (W) may be disposed in a processing space C10 within a processing chamber (C) during the substrate treatment process. At this time, when the treatment liquid is supplied to the spray nozzle by the liquid supply unit 900, the spray nozzle may apply the treatment liquid onto the substrate (W), thereby performing a treatment process (hereinafter, referred to as a substrate treatment process) on the substrate (W).

Hereinafter, the description will be centered on an embodiment in which the liquid supply unit 900 is connected to the application module 401 and supplies a treatment liquid (for example, photoresist) to the nozzle portion 412, but the present disclosure is not limited thereto. In this case, the processing chamber (C) may be a coating chamber 410.

The pump unit is designed to discharge a fixed amount of treatment liquid onto the substrate (W). At this time, the pump unit may be provided as a multi-stage pump structure including a first pump portion 930 and a second pump portion 940. For example, the first pump portion 930 and the second pump portion 940 may be diaphragm-type pumps, but are not limited thereto.

The control unit may control the supply pressure of the pump unit to significantly reduce pressure changes in the supply pipe (L) between the pump unit and the nozzle portion 412 of the substrate treatment apparatus 1, as described in detail below.

The storage container 910 may include an internal space. The internal space may accommodate a treatment liquid. The storage container 910 may be connected to a trap tank 920 via a first supply line L10.

The treatment liquid may be transported from the storage container 910 to the trap tank 920 via the first supply line L10. For example, the storage container 910 may be disposed while being contained in the internal space of an external container (not illustrated). In this case, a pressurized gas supply line (not illustrated) may be connected to the external container. When pressurized gas is supplied to the internal space of the external container via the pressurized gas supply line, the pressure of the internal space may increase to a predetermined pressure. As a result, an internal pressure difference may occur between the external container and the trap tank 920. Due to this internal pressure difference, the treatment liquid may be transported to the trap tank 920 via the first supply line L10. The pressurized gas may be an inert gas such as nitrogen gas or helium gas.

In the above case, a first valve V10 may be disposed on the first supply line L10. The first valve V10 may open and close the first supply line L10 to transfer the treatment liquid to the trap tank 920 or to stop the transfer of the treatment liquid. Furthermore, the control unit may control the opening of the first valve V10, thereby controlling the flow rate of the treatment liquid passing through the first supply line L10.

The trap tank 920 may temporarily store the treatment liquid supplied through the first supply line L10. For example, a water level sensor (not illustrated) may be installed on one side of the trap tank 920 to detect the water level of the treatment liquid stored in the trap tank 920. Therefore, the trap tank 920 may be continuously filled with treatment liquid up to an appropriate water level.

Meanwhile, the top of the trap tank 920 may be connected to a drain line (not illustrated). The drain line may remove air bubbles that collect at the top of the trap tank 920 or passively drain the treatment liquid in response to changes in the properties of the treatment liquid. The air bubbles and the changed treatment liquid discharged through the drain line may be discharged to a waste tank (not illustrated).

A second supply line L20 may be connected to the bottom of the trap tank 920. The trap tank 920 may be connected to the first pump portion 930 via the second supply line L20. Through the second supply line L20, a single amount of treatment liquid for the substrate (W), filled in the trap tank 920, may be supplied to the first pump portion 930.

The pump unit includes a first pump portion 930 and a second pump portion 940, and may supply treatment liquid to the nozzle portion 412 using the fluid pressure generated by the suction and discharge operations.

The first pump portion 930 may be disposed between the second pump portion 940 and the storage container 910. The first pump portion 930 may be connected to a trap tank 920 via a second supply line L20. The first pump portion 930 may receive treatment liquid stored in the trap tank 920 via the second supply line L20. At this time, the first pump portion 930 may include a first pump chamber (not illustrated). The first pump chamber may be filled with a certain amount of treatment liquid supplied to the first pump portion 930 via the second supply line L20.

In the above case, a second valve V20 may be disposed in the second supply line L20. The second valve V20 may open and close the second supply line L20 to either transport the treatment liquid to the first pump portion 930 or to stop the transport of the treatment liquid. Furthermore, the control unit may control the flow rate of the treatment liquid passing through the second supply line L20 by adjusting the opening of the second valve V20.

Furthermore, the first pump portion 930 may be connected to the second pump portion 940 via the third supply line L30. The treatment liquid filled in the first pump chamber may be supplied to the second pump portion 940 via the third supply line L30. The supply pressure of the treatment liquid to the second pump portion 940 from the first pump portion 930 may be controlled by the control unit to maintain a constant pressure.

In the above case, a third valve V30 may be disposed in the third supply line L30. The third valve V30 may open and close the third supply line L30 to transfer the treatment liquid to the second pump portion 940 or to stop the transfer of the treatment liquid. In addition, the control unit may control the supply flow rate of the treatment liquid passing through the third supply line L30 by adjusting the opening degree of the third valve V30.

The second pump portion 940 may be connected to the first pump portion 930 via the third supply line L30. The second pump portion 940 may include a second pump chamber (not illustrated). The second pump chamber may be filled with a certain amount of treatment liquid supplied to the second pump portion 940 via the third supply line L30. In more detail, a single amount of the treatment liquid for one substrate (W) filled in the first pump chamber may be transferred to and filled into the second pump chamber via the third supply line L30.

The second pump portion 940 may supply the treatment liquid filled in the second pump chamber to the nozzle portion 412 via the fourth supply line L40. At this time, the second pump portion 940 may supply a fixed amount of treatment liquid to the nozzle portion 412. In more detail, the second pump portion 940 may suck a single amount of treatment liquid for the substrate (W) from the first pump portion 930 into the second pump chamber (not illustrated), and then discharge the treatment liquid through the nozzle portion 412 at a constant pressure and flow rate during application.

In the above case, a fourth valve V40 may be disposed on the fourth supply line L40. The fourth valve V30 may open and close the fourth supply line L40 to either transport the treatment liquid to the nozzle portion 412 or to stop the transport of the treatment liquid. Furthermore, the control unit may control the flow rate of the treatment liquid passing through the fourth supply line L40 by adjusting the opening of the fourth valve V30.

Meanwhile, a filter (not illustrated) may be disposed along the treatment liquid path. For example, a filter may be disposed on the third supply line L30, which is the path through which the treatment liquid travels from the first pump portion 930 to the second pump portion 940. The filter may filter foreign substances contained in the treatment liquid moving to the nozzle portion 412 through the supply pipe (L).

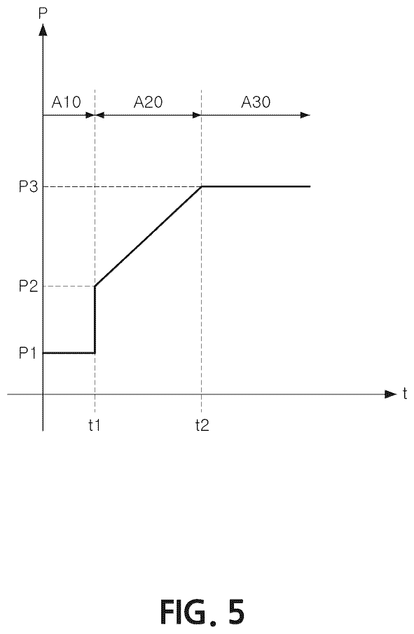

FIG. 5 is a graph schematically illustrating the state in which the supply pressure of a treatment liquid changes while the treatment liquid moves in a substrate treatment apparatus including a liquid supply unit according to an embodiment.

Referring to FIG. 5, a control unit (not illustrated) may control the operation of the pump units, for example, the first pump portion 930 and the second pump portion 940. The control unit may be implemented, for example, in the form of a circuit board mounted on the liquid supply unit 900 or the control computer of the pump unit, a computer chip mounted on the circuit board, software embedded in a computer chip or the control computer, or the like.

As described above, the treatment liquid stored in the storage container 910 may be supplied to the first pump portion 930 by sequentially passing through the first supply line L10 and the second supply line L20. The supplied treatment liquid may be filled in a predetermined amount in the first pump chamber. Before the treatment liquid is supplied to the second pump portion 940 and begins to fill the second pump chamber, the third valve V30 may be closed. Thus, the period before the treatment liquid filled in the first pump chamber is supplied to the second pump portion 940 is defined as a “wating period A10.”

In the wating period A10, the interior of the third supply line L30 may be maintained in a pressurized state at a constant pressure (hereinafter, referred to as atmospheric pressure) P1. In more detail, the third supply line L30, closed by the third valve V30, is pressurized by the treatment liquid supplied from the second pump portion 940, thereby maintaining the pressure within the third supply line L30 at the atmospheric pressure P1. This is to prevent negative pressure from occurring in the third supply line L30 at a point in time t1 when the third valve V30 opens and the treatment liquid begins to fill the second pump portion 940.

When the wating period A10 is maintained and the third valve V30 opens, the treatment liquid may begin to be supplied to the second pump portion 940 through the third supply line L30 at an initial pressure P2. The initial pressure P2 may be higher than the atmospheric pressure P1. Thereafter, the treatment liquid may be supplied to the second pump portion 940 as the supply pressure (P) thereof changes from the initial pressure P2 to the target pressure P3 over time (t). Thus, the period from the point in time t1 when the treatment liquid begins to be supplied to the second pump portion 940 to a point in time t2 when the supply pressure (P) of the treatment liquid reaches the target pressure P3 is defined as a “variable period A20”.

Once the supply pressure (P) reaches the target pressure P3, the treatment liquid may be supplied to the second pump portion 940 at the target pressure P3. Thus, the period from the point in time t2 when the supply pressure (P) of the treatment liquid reaches the target pressure P3 until the treatment liquid is fully filled in the second pump chamber is defined as the “filling period A30”. After the filling period A30, a certain amount of treatment liquid (for example, a single amount thereof, for the substrate (W)) may be filled in the second pump chamber.

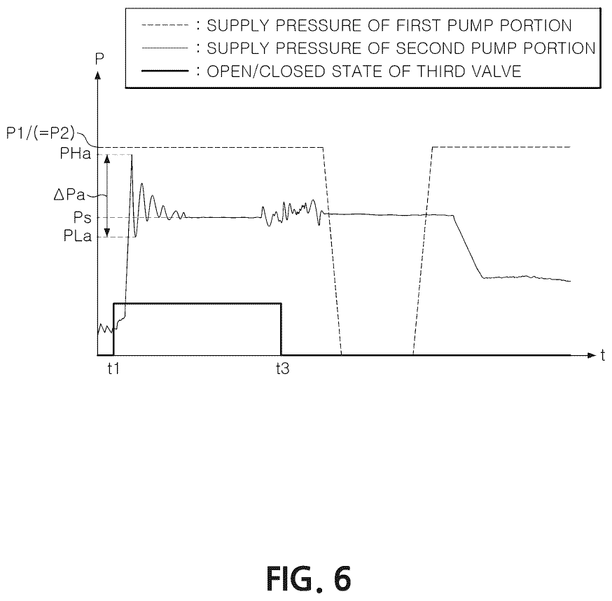

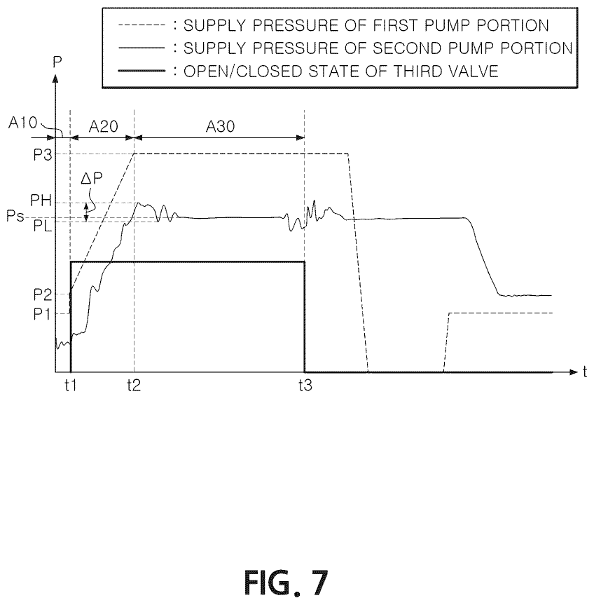

FIG. 6 is a graph illustrating changes in the supply pressure of a treatment liquid for each movement section of the treatment liquid in a substrate treatment apparatus including a liquid supply unit of the related art. FIG. 7 is a graph illustrating changes in the supply pressure of a treatment liquid according to each movement section of the treatment liquid in a substrate treatment apparatus including a liquid supply unit according to an embodiment of the present disclosure.

Referring to FIG. 6, in the liquid supply unit according to the comparative example, as described above, to prevent negative pressure from forming in the third supply line L30 when the third valve V30 is opened, the third supply line L30 may be maintained at a constant pressure (for example, atmospheric pressure) P1′ by the first pump portion 930. When the third valve V30 is opened, the treatment liquid may be supplied to the second pump portion 940 at the aforementioned atmospheric pressure P1′.

However, when the third valve V30, which has been closed and pressurized to the atmospheric pressure P1′ higher than the target supply pressure (Ps), is opened, the treatment liquid suddenly starts to move to the second pump portion 940, which may cause a pressure hunting phenomenon within the supply pipe. In this case, the ‘target supply pressure (Ps)’ may refer to the supply pressure of the treatment liquid supplied to the nozzle portion 412 by the second pump portion 940. Accordingly, when filled into the second pump portion 940, the supply pressure (P) of the treatment liquid may rapidly increase and decrease and fluctuate between the ‘minimum pressure (PLa)’ lower than the target supply pressure (Ps) and the ‘maximum pressure (PHa)’ higher than the target supply pressure (Ps).

As such, if excessive pressure fluctuations occur within the third supply line L30, not only will microbubbles be generated, but water hammer may also damage the third supply line L30. Furthermore, such pressure fluctuations within the supply pipe may reduce the control efficiency of the pump unit, ultimately reducing the efficiency of the substrate treatment process using the treatment liquid. Furthermore, as the difference between the atmospheric pressure P1′ and the target supply pressure (Ps) increases, the pressure difference (ΔPa) between the maximum and minimum pressures (Pla and PHa) increases, exacerbating the aforementioned pressure hunting phenomenon.

Referring to FIG. 7, in the liquid supply unit 900 according to an embodiment of the present disclosure, in the wating period A10, the first pump portion 930 may pressurize the third supply line L30 to atmospheric pressure P1. Unlike the comparative example, at this time, the atmospheric pressure P1 may be lower than the target supply pressure (Ps) of the second pump portion 940. When the third valve V30 is opened, the initial pressure P2, which is a pressure increased to a pressure higher than atmospheric pressure P1, may be applied to the second pump portion 940. Furthermore, when the third valve V30 is opened, the treatment liquid may be transported to the second pump portion 940 via the third supply line L30.

Thereafter, in the variable period A20, the supply pressure (P) of the first pump portion 930 may be increased higher than the initial pressure P2 when the third valve V30 is opened. In more detail, the supply pressure (P) of the treatment liquid by the first pump portion 930 may be controlled to gradually increase from the initial pressure P2 over time (t) and to reach the target pressure P3 after a predetermined period of time. At this time, the target pressure P3 may be higher than the target supply pressure (Ps) of the second pump portion 940. Therefore, the treatment liquid may be prevented from flowing back into the first pump portion 930 while being supplied into the second pump portion 940 and/or while being supplied to the nozzle portion 412.

Once the target pressure P3 is reached, the increase of the supply pressure (P) of the treatment liquid by the first pump portion 930 may be stopped. For example, during the filling period A30, the treatment liquid may be maintained at the target pressure P3 and supplied to the second pump portion 940. Meanwhile, after reaching the target pressure P3, a pressure drop may occur while the treatment liquid is being filled into the second pump chamber. To compensate for this pressure drop, feedback control using a pressure sensor (not illustrated), described later, may be performed during the filling period A30. Through feedback control, the supply pressure (P) of treatment liquid may be maintained at the target pressure P3 throughout the filling period A30.

As described above, the first pump portion 930 may continue to supply the treatment liquid at a constant pressure (for example, target pressure) P3 until a certain amount of treatment liquid is filled into the second pump chamber. Then, when the filling of a single amount of the treatment liquid for the substrate (W) into the second pump chamber is completed, the third valve V30 may be closed again.

As described above, the atmospheric pressure P1 is maintained lower than the target supply pressure (Ps), and the supply pressure (P) of the treatment liquid is controlled to gradually increase to the target pressure P3 from an opening time t3 of the third valve V30. Therefore, when the treatment liquid is filled into the second pump portion 940, pressure hunting in the supply pipe may be significantly reduced.

In more detail, the pressure difference (ΔP) between the maximum pressure (PH) and minimum pressure (PH) in the third supply line L30 and the difference between the maximum/minimum pressures (PL and PH) and the target supply pressure (Ps) may occur only to a small degree, compared to the comparative example described above. For example, by reducing increase/decrease fluctuations in the supply pressure (P) within the third supply pipe (L), the aforementioned pressure hunting phenomenon, damage to the supply pipe due to water hammer, and the generation of microbubbles within the treatment liquid may be significantly reduced. Furthermore, as pressure fluctuations within the supply pipe are reduced, the control efficiency of the pump unit increases, resulting in improved efficiency in the substrate treatment process using the treatment liquid.

Meanwhile, as described above, the adjustment of the treatment liquid supply pressure (P) of the first pump portion 930 and the opening and closing of the third valve V30 may be controlled by the control unit.

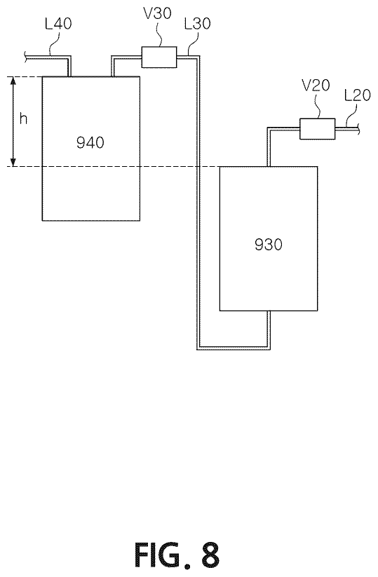

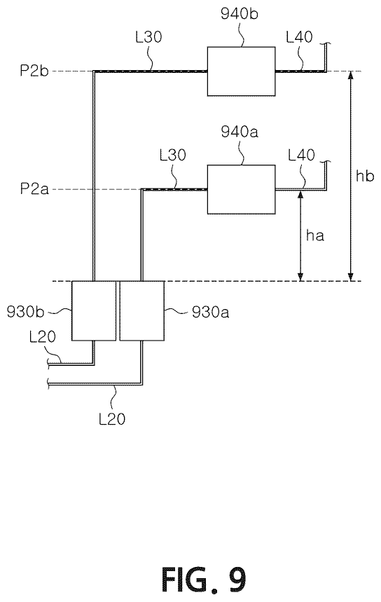

FIG. 8 illustrates a portion of the liquid supply unit of FIG. 4. FIG. 9 illustrates a portion of a liquid supply unit according to another embodiment.

Referring to FIG. 8, the second pump portion 940 may be disposed at a higher position than the first pump portion 930. A height difference (h) may be present between the first pump portion 930 and the second pump portion 940. If this height difference (h) exists, a loss of supply pressure (P) may occur when the treatment liquid is supplied by the first pump portion 930. In this case, the control unit may compensate for this loss of supply pressure (P) by adjusting the initial pressure P2 based on the height difference (h).

Referring to FIG. 9, a first height difference (ha) may exist between the first pump portion (hereinafter, “1-1 pump unit”) 930aillustrated on the right and the second pump portion (hereinafter, “2-1 pump unit”) 940a connected thereto. A second height difference (hb) may exist between the first pump portion (hereinafter, “1-2 pump unit”) 930b illustrated on the left and the second pump portion (hereinafter, “2-2 pump unit”) 940b connected thereto. At this time, the second height difference (hb) may be greater than the first height difference (ha). In this case, the control unit may control the first pump portion 930 so that the initial pressure P2 increases or decreases in proportion to the height difference (h) between the pump units. For example, in the case in which the second height difference (hb) is twice the first height difference (ha), the initial pressure P2 of the 1-2 pump unit 930b may be controlled to be twice the initial pressure P2 of the 1-1 pump unit 930a.

As described above, even when the height difference (h) between the first and second pump portions 930 and 940 changes due to various causes that may occur during the substrate processing process, the pressure loss occurring in the pump unit may be compensated for by controlling the initial pressure P2 to increase or decrease in proportion to the change in the height difference (h). Therefore, when transporting and filling the treatment liquid within the liquid supply unit 900, a decline in work efficiency due to the occurrence or change of the above-mentioned height difference (h) may be prevented.

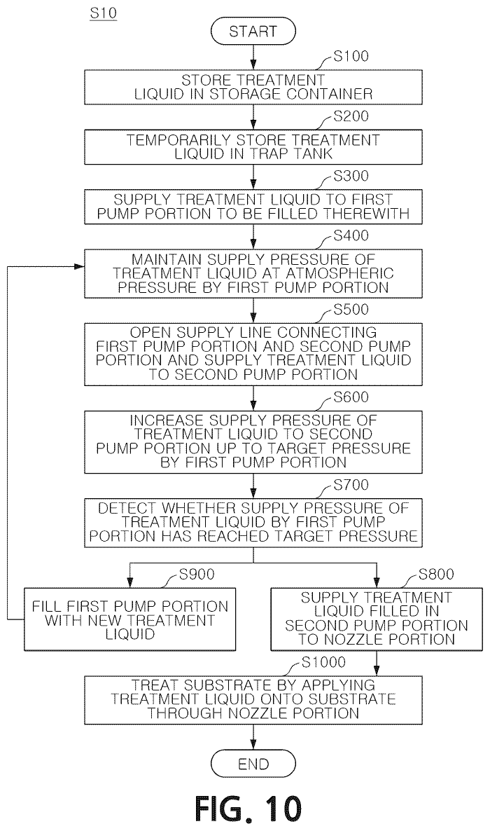

FIG. 10 is a flowchart illustrating a substrate treatment method according to an embodiment.

Referring to FIG. 10, a method for processing a substrate (W) (hereinafter referred to as “substrate treatment method”) (S10) by a substrate treatment apparatus 1 including the liquid supply unit 900 as described above may be as follows.

First, a treatment liquid may be stored in a storage container 910 (S100). In operation S100, the treatment liquid may be filled into the storage container 910 using various methods. For example, a storage container 910 pre-filled with the treatment liquid may be supplied to the liquid supply device 900 by a separate supply device (not illustrated), and then, a first supply line L10 may be connected to the storage container 910. As another example, while a separate supply line (not illustrated) is connected to the storage container 910, when the treatment liquid previously filled in the storage container 910 is completely withdrawn, a new treatment liquid may be supplied to the storage container 910 through the supply line.

Next, the treatment liquid may be temporarily stored in the trap tank 920 (S200). In operation S200, the treatment liquid stored in the storage container 910 may be transferred into the trap tank 920 via the first supply line L10. This treatment liquid may be temporarily stored in the trap tank 920 before being supplied to the first pump portion 930. At this time, a certain amount of treatment liquid may be temporarily stored in the trap tank 920. For example, a single amount of the treatment liquid for the substrate (W) may be stored in the trap tank 920.

Next, the treatment liquid may be supplied to the first pump portion (S300). In operation S300, the treatment liquid temporarily stored in the trap tank 920 may be transferred to the first pump portion 930 through the second supply line L20. Accordingly, the second pump room may be filled with a predetermined amount of the treatment liquid as described above.

Next, the first pump portion 930 may maintain the supply pressure (P) of the treatment liquid at the atmospheric pressure P1 (S400). In operation S400, the third valve V30 may be kept closed. In this case, the first pump portion 930 may supply the treatment liquid to the third supply line L30 so that the pressure within the third supply line L30 is maintained at the atmospheric pressure P1. At this time, the atmospheric pressure P1 may be controlled to be lower than the ‘target supply pressure (Ps)’, which is the pressure at which the second pump portion 940 supplies the treatment liquid to the nozzle portion 412 as described above. In operation S400, the first pump portion 930 may maintain the supply pressure (P) constantly at the atmospheric pressure P1 until the third valve V30 opens.

Next, the third supply line L30, connecting the first pump portion 930 and the second pump portion 940, opens, and the treatment liquid may be supplied to the second pump portion 940 (S500). At operation S500, when the third valve V30 opens and the treatment liquid begins to be supplied to the second pump portion 940, the supply pressure (P) of the treatment liquid may be increased to the initial pressure P2. This increase in supply pressure (P) may be controlled by the control unit.

Next, the first pump portion may increase the supply pressure of the treatment liquid to the second pump portion to the target pressure (S600). In operation S500, the supply pressure (P) gradually increases over time (t) from the point in time t1 when the third valve V30 opens, reaching the target pressure P3. At this time, the target pressure may be higher than the target supply pressure (Ps) of the second pump portion 940 described above.

Next, it may be detected whether the supply pressure (P) of the treatment liquid by the first pump portion 930 has reached the target pressure P3 (S700). In operation S700, the supply pressure (P) of the treatment liquid supplied to the second pump portion 940 through the third supply line L30 may be detected in real time and at predetermined intervals. To this end, the liquid supply unit 900 may include a pressure sensor (not illustrated). The pressure sensor may be disposed in the third supply line L30 or the second pump portion 940.

Additionally, operation S700 may be performed concurrently with operations S500 and S600 at predetermined intervals. The pressure sensor may be electrically connected to the control unit. During operation S700, the pressure sensor may transmit the detected value of the supply pressure (P) to the control unit.

If the control unit confirms that the detected value of the supply pressure (P) received from the pressure sensor has reached the target pressure P3, the control unit may control the treatment liquid to begin filling into the second pump chamber of the second pump portion 940. Accordingly, after a predetermined time (t) elapses from the point in time t1 when the third valve V30 opens, the supply pressure (P) is increased to the target pressure P3 and then, the treatment liquid may be supplied to the second pump portion 940. Accordingly, the second pump portion 940 operates while the supply pressure (P) of the treatment liquid supplied from the first pump portion 930 is sufficiently high, preventing the treatment liquid from flowing back to the first pump portion 930 through the third supply line L30 or from pressure loss during treatment liquid filling. Furthermore, microbubbles, which may occur during the initial pressure increase period of the supply pressure (P) after the third valve V30 opens when the treatment liquid is supplied to the second pump portion 940, may be significantly reduced. This may resolve various issues, such as uneven application of the treatment liquid due to microbubbles when applying the treatment liquid to the substrate (W) through the nozzle portion 412, distortion of the pattern formed on the substrate, or occurrence of defects during subsequent processing.

The second pump portion 940 may be filled with a predetermined amount of the treatment liquid in the second pump chamber thereof.

Next, the treatment liquid filled in the second pump portion 940 is supplied to the nozzle portion 412 (S800), and a substrate treatment operation (S1000) in which the treatment liquid is applied onto the substrate (W) through the nozzle portion 412 may be performed. In operation S800, the second pump portion 940 may supply the treatment liquid to the nozzle portion 412 through the fourth supply line L40. For example, the second pump room may be filled with one dose of the treatment liquid for the substrate (W). In this case, the nozzle portion 412 may receive a single dose of treatment liquid from the second pump portion 940.

Thereafter, the nozzle portion 412 may perform a substrate processing operation of applying the single dose of treatment liquid onto the substrate (W) disposed within the processing chamber (C) (for example, the processing space C10) to form a photoresist film on the surface of the substrate (W).

Meanwhile, in operation S700, once the treatment liquid previously filled in the first pump portion 930 has been completely supplied to the second pump portion 940, a new treatment liquid may be supplied to the first pump portion 930 (S900).

For example, operation S900 may be performed after the treatment liquid previously filled in the first pump portion 930 has completely moved to the second pump portion 940 via the third supply line L30. Once the previously filled treatment liquid has been completely removed and the first pump chamber is empty, the third valve V30 may be closed again by the control unit. New treatment liquid may then flow into the empty first pump chamber through the second supply line L20. As described above, the new treatment liquid may be sequentially passed through the storage container 910 and the trap tank 920 and then supplied to the first pump portion 930.

Therefore, the first pump chamber of the first pump portion 930 may be refilled with a predetermined amount of treatment liquid as described above. The newly filled treatment liquid is then supplied to the nozzle portion 412 via the second pump portion 940 for use in processing the next substrate (W). Since the supply and control methods to the nozzle portion 412 are identical or similar to those described above, a detailed description will be omitted.

Once the treatment liquid supply process using the liquid supply unit 900 and the treatment liquid application process (substrate treatment process) through the nozzle portion 412 are completed, the treated substrate (W) may be discharged from the processing chamber (C). A new substrate (W) is then supplied to the processing chamber (C), and the treatment liquid supply and application process according to the substrate treatment method (S10) described above may be repeated.

The substrate treatment apparatus 1 and substrate treatment method (S10) according to embodiments of the present disclosure as described above are configured such that when supplying the treatment liquid to the nozzle portion 412 using the liquid supply unit 100, the treatment liquid is supplied from the trap tank 920 to the second pump portion 940 via the first pump portion 930, thereby preventing negative pressure from forming within the supply pipe (L).

Furthermore, by reducing the water hammer phenomenon and pressure hunting that may occur in the pump unit while the treatment liquid is moving through the liquid supply device 900, damage to the supply pipe (L) and defects of the substrate (W) due to microbubble generation may be prevented.

In the above examples, the substrate treatment apparatus in the present disclosure has been described as an embodiment applied to a photolithography process, but the present disclosure is not limited thereto, and it is obvious to those skilled in the art that the present disclosure may be applied to various processes such as substrate etching processes, testing, and packaging processes, and this also falls within the scope of the present disclosure.

As set forth above, a substrate treatment apparatus and a substrate treatment method according to embodiments may prevent negative pressure from forming within the supply pipe by configuring the treatment liquid to be supplied from a trap tank to a second pump portion via a first pump portion during the process of supplying the treatment liquid to the nozzle portion using a liquid supply unit.

Furthermore, by reducing the occurrence of water hammer and pressure hunting that may occur in the pump unit while the treatment liquid is moving through the liquid supply device, damage to the supply pipe or defects in the substrate due to occurrence of microbubbles may be prevented.

While example embodiments have been illustrated and described above, it will be apparent to those skilled in the art that modifications and variations could be made without departing from the scope of the present disclosure as defined by the appended claims.

1. A substrate treatment apparatus comprising:
a nozzle portion configured to apply a treatment liquid to a substrate; and
a liquid supply unit configured to supply the treatment liquid to the nozzle portion,
wherein the liquid supply unit includes,
a storage container configured to store the treatment liquid;
a pump unit including a first pump portion filled with the treatment liquid before being supplied to the nozzle portion, and a second pump portion supplying the treatment liquid to the nozzle portion, the first pump portion being connected to the second pump portion via a supply pipe and controlling supply pressure of the treatment liquid supplied to the second pump portion;
a valve configured to open and close the supply pipe; and
a control unit configured to maintain the supply pressure at atmospheric pressure when the valve is closed and to control the supply pressure to vary to a target pressure when the valve is opened.

2. The substrate treatment apparatus of claim 1, wherein the liquid supply unit further includes a trap tank which is disposed between the storage container and the first pump portion and in which the treatment liquid is temporarily stored before being supplied to the first pump portion.

3. The substrate treatment apparatus of claim 2, wherein the storage container is connected to the trap tank via a first supply line, the trap tank is connected to the first pump portion via a second supply line, and the second pump portion is connected to the first pump portion via a third supply line and connected to the nozzle portion via a fourth supply line, and
the treatment liquid stored in the storage container is supplied to the nozzle portion by sequentially passing through the first supply line, the second supply line, the third supply line, and the fourth supply line.

4. The substrate treatment apparatus of claim 1, wherein the atmospheric pressure is lower than the target pressure.

5. The substrate treatment apparatus of claim 4, wherein, when the valve is opened and the treatment liquid begins to be supplied to the second pump portion, the pressure increases to an initial pressure higher than the atmospheric pressure.

6. The substrate treatment apparatus of claim 5, wherein the control unit gradually increases the supply pressure until the supply pressure reaches the target pressure, after the valve is opened, and controls the treatment liquid to be filled into the second pump portion after the supply pressure reaches the target pressure.

7. The substrate treatment apparatus of claim 6, wherein the control unit controls a new treatment liquid to be filled into the first pump portion after the supply pressure reaches the target pressure.

8. The substrate treatment apparatus of claim 5, wherein the second pump portion is disposed at a higher position than the first pump portion.

9. The substrate treatment apparatus of claim 8, wherein the initial pressure is adjusted based on a height difference between the first pump portion and the second pump portion.

10. The substrate treatment apparatus of claim 9, wherein the control unit controls the first pump portion so that the initial pressure increases or decreases in proportion to the height difference.

11.-19. (canceled)

20. A substrate treatment apparatus comprising:
a processing chamber having a processing space provided therein;
a nozzle portion disposed in the processing space and applying a treatment liquid to a substrate; and
a liquid supply unit supplying the treatment liquid to the nozzle portion,
wherein the liquid supply unit includes,
a storage container storing the treatment liquid;
a trap tank connected to the storage container via a first supply line and temporarily storing the treatment liquid;
a pump unit including a first pump portion connected to the trap tank via a second supply line, receiving the treatment liquid temporarily stored in the trap tank, and filled with the treatment liquid, and a second pump portion connected to the first pump portion via a third supply line and supplying the treatment liquid to the nozzle portion via a fourth supply line, wherein the first pump portion regulates supply pressure of the treatment liquid supplied to the second pump portion via the third supply line;
a valve opening and closing the third supply line. and
a control unit configured to variably control the supply pressure of the treatment liquid,
wherein the control unit is configured to control the supply pressure to be maintained at atmospheric pressure when the valve is closed, and to control the supply pressure to increase to a target pressure when the valve is opened,
the control unit is configured to control the supply pressure to increase to an initial pressure higher than the atmospheric pressure when the valve is opened, and then to gradually increase to the target pressure over time, and to control the treatment liquid to begin to be filled into the second pump portion after the supply pressure reaches the target pressure, and
the control unit is configured to control the valve to be closed again and to fill a new treatment liquid in the first pump portion, when the supply pressure reaches the target pressure and then the treatment liquid previously filled in the first pump portion is completely supplied to the second pump portion, and to control the supply pressure of the treatment liquid in the third supply line to become the atmospheric pressure.
